(19) United States
(12) Patent Application Publication
(10) Pub. No.: US 2003/0193787 A1
(43) Pub. Date: Oct. 16, 2003

(54) Structure of mounting flexible wiring board

(76) Inventors: Satoru Manabe, Kanagawa (JP); Kiyofumi Sato, Kanagawa (JP); Tsuneo Uwabo, Kanagawa (JP)

Correspondence Address: WHITHAM, CURTIS & CHRISTOFFERSON, P.C., 11491 SUNSET HILLS ROAD, SUITE 340, RESTON, VA, 20190, US

(21) Appl. No.: 10/412,337

(22) Filed: Apr. 14, 2003

(30) Foreign Application Priority Data
Apr. 15, 2002 (JP) P2002-112571

(51) Int. Cl. H05K 5/00; H05K 5/04; H05K 5/06

(52) U.S. Cl. 361/752

(57) ABSTRACT

A structure of mounting a flexible wiring board, includes a strap-like flexible wiring board, a base member, a moving member and a shape-restricting member. The strap-like flexible wiring board has a first curvature portion curved in a substantially inverted manner with its front and rear sides reversed, a second curvature portion curved in a direction opposite to a direction of curvature of the first curvature portion and an intermediate portion disposed between the first and second curvature portions. The base member has a first fixing portion which fixes a first end portion of the flexible wiring board. The moving member is mounted for movement relative to the base member. The moving member has a second fixing portion which fixes the second end portion of the flexible wiring board. The shape-restricting member restricts a shape of the intermediate portion so that a part of the intermediate portion is deformed to project into a convex shape when viewed from a side thereof.

### BACKGROUND OF THE INVENTION

This invention relates to a structure of mounting a flexible wiring board (flexible circuit board) mounted, for example, on an optical disk device.

In a disk device for an optical disk such as a compact disk (CD), a spindle motor for rotating the optical disk, as well as an optical pickup for optically reading information recorded in the rotating optical disk, is mounted on a feed chassis pivotally mounted on a device body. In this case, the optical pickup need to be moved in a direction of a radius of the optical disk, and therefore is mounted on a slider which is reciprocally movable in this direction.

In order to feed signals detected by the optical pickup and also to drive and control an actuator contained in the optical pickup, the optical pickup is connected to a circuit board by a long flexible wiring board, and terminals of the optical pickup are electrically connected to corresponding terminals of the circuit board, respectively. This flexible wiring board is a long strap-like member, and this member is disposed in a generally S-shaped curved condition, and has a length to sufficiently cover the range of movement of the slider.

However, such a related flexible wiring board-mounting structure has the following drawbacks.

The shape of the S-shaped curved flexible wiring board varies with the movement of the slider, and a slack portion develops in this flexible wiring board, depending on the position of the slider. And, a warp (so-called curling) in a direction of a width of the flexible wiring board develops in this slack portion, so that there occurs a phenomenon in which the resistance to the movement of the slider suddenly increases. When the slider is moved in a predetermined direction in a curling-developed condition, the curvature of the curled portion is suddenly inverted, and at this time an abnormal sound (heard as a sound “peko”) is produced. And besides, the curled portion has so far prevented the flexible wiring board from being curved in the longitudinal direction, and since this curled force is instantaneously eliminated, the flexible wiring board is suddenly curved in the longitudinal direction, and flutters to produce, in some cases, a force tending to instantaneously push the slider. Therefore, there have been encountered a problem that the curling (warp in the direction of the width) of the flexible wiring board prevents the smooth movement of the slider, and becomes a cause of the lowered reliabilities of the information reading, etc.

### SUMMARY OF THE INVENTION

It is therefore an object of the present invention to provide a structure of mounting a flexible wiring board which enables a smooth movement of a moving member.

The above object has been achieved by the invention recited in the following Paragraphs (1) to (13).

(1) A structure of mounting a flexible wiring board comprising:

a strap-like flexible wiring board, including;

a first curvature portion curved in a substantially inverted manner with its front and rear faces reversed;

a second curvature portion curved in a direction opposite to a direction of curvature of the first curvature portion; and

an intermediate portion disposed between the first and second curvature portions;

a base member, having a first fixing portion which fixes a first end portion of the flexible wiring board;

a moving member, mounted for movement relative to the base member, and the moving member having a second fixing portion which fixes the second end portion of the flexible wiring board; and

a shape-restricting member, restricting a shape of the intermediate portion so that a part of the intermediate portion is deformed to project into a convex shape when viewed from a side thereof.

(2) A structure of mounting a flexible wiring board according to Paragraph (1), wherein the shape-restricting member includes a support portion fixedly supporting a portion of the intermediate portion of the flexible wiring board, and at least one pressing portion of a convex shape which is disposed in the vicinity of the support portion, and which presses other portion of the portion of the intermediate portion.

(3) A structure of mounting a flexible wiring board according to Paragraph (2), wherein the pressing portion is disposed between the support portion and the first curvature portion.

(4) A structure of mounting a flexible wiring board according to Paragraph (2), wherein the at least one pressing portion is a first pressing portion and a second pressing portion;

wherein the first pressing portion is disposed between the support portion and the first curvature portion; and

wherein the second pressing portion is disposed between the support portion and the second curvature portion.

(5) A structure of mounting a flexible wiring board according to Paragraph (4), wherein the first pressing portion is larger in height than the second pressing portion.

(6) A structure of mounting a flexible wiring board according to any one of Paragraphs (2) to (5), wherein the support portion retains or fixes opposite side edges of the intermediate portion.

(7) A structure of mounting a flexible wiring board according to any one of Paragraphs (2) to (6), wherein the support portion and the pressing portion are provided on a plate-like member disposed between the base member and the moving member.

(8) A structure of mounting a flexible wiring board according to Paragraph (7), wherein the pressing portion has a rib projected substantially perpendicularly from the plate-like member.

(9) A structure of mounting a flexible wiring board according to any one of Paragraphs (2) to (8), wherein a distal end of the pressing portion has a rounded shape.

(10) A structure of mounting a flexible wiring board according to any one of Paragraphs (1) to (9), wherein the position of the second curvature portion in the flexible wiring board is displaced in accordance with the movement of the moving member.

(11) A structure of mounting a flexible wiring board according to any one of Paragraphs (1) to (10), wherein a radius of curvature of the second curvature portion varies in accordance with the movement of the moving member, while a radius of curvature of the first curvature portion is generally constant.

(12) A structure of mounting a flexible wiring board according to any one of Paragraphs (1) to (11), wherein a maximum value of a radius of curvature of the second curvature portion is larger than a radius of curvature of the first curvature portion.

(13) A structure of mounting a flexible wiring board according to any one of Paragraphs (1) to (12), wherein the moving member carries an optical pickup having the function to read information recorded in an optical disk.

In the above configuration, the curling (warp in the direction of the width) of the flexible wiring board is prevented from being produced, and as a result the production of an abnormal sound due to the development/elimination of the curling is prevented, and besides the movement of the moving member can be effected smoothly. Therefore, the reliability of the device having this flexible wiring board-mounting structure, is enhanced.

### BRIEF DESCRIPTION OF THE DRAWINGS

The above objects and advantages of the present invention will become more apparent by describing in detail preferred exemplary embodiments thereof with reference to the accompanying drawings, wherein:

FIG. 1 is a side-elevational view of a flexible wiring board-mounting structure according to a preferred embodiment of the present invention;

FIG. 2 is a side-elevational view showing the flexible wiring board-mounting structure according to the preferred embodiment of the present invention; and

FIG. 3 is a view as seen from the line A-A of FIG. 1.

### DETAILED DESCRIPTION OF THE PREFERRED EMBODIMENTS

A preferred embodiment of a flexible wiring board-mounting structure of the present invention will now be described in detail with reference to the accompanying drawings.

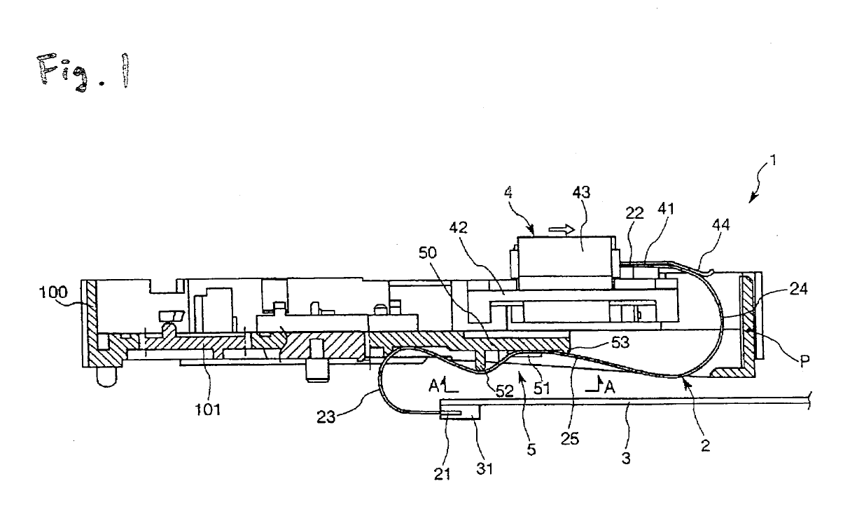

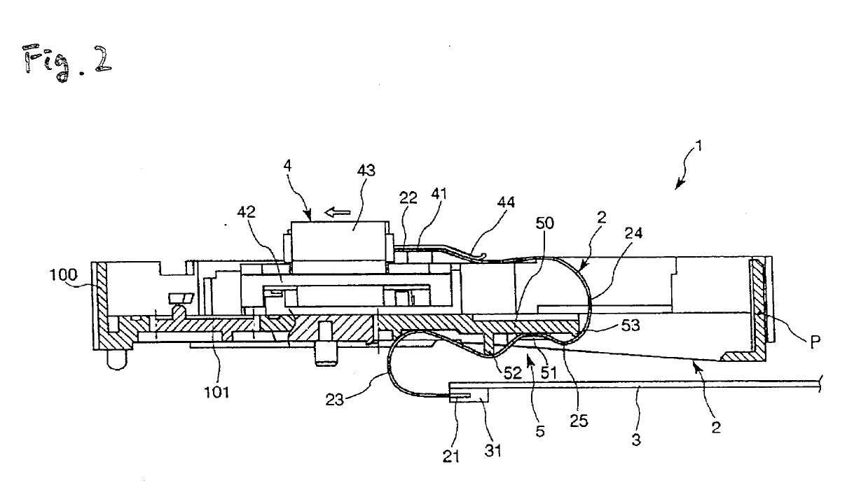

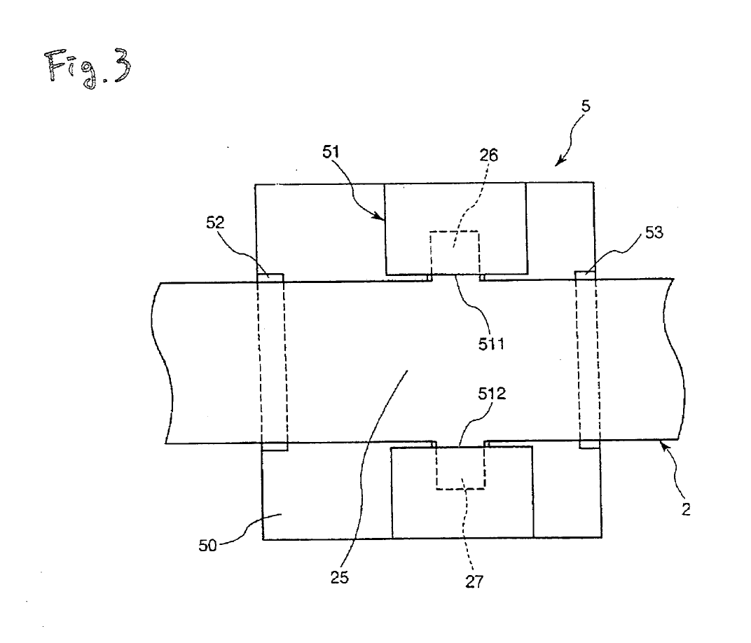

FIGS. 1 and 2 are a side-elevational view showing the embodiment of the flexible wiring board-mounting structure of the invention, and FIG. 3 is a view as seen from the line A-A of FIG. 1.

The flexible wiring board-mounting structure 1, shown in FIG. 1, is mounted, for example, on a disk device which drives and rotates an optical disk (such as a compact disk (CD), a CR-ROM, a CR-R, a CD-WR, a DVD-R and a DVD-WR), and has the function of reading information recorded in this optical disk (and further has, in some cases, the function of writing information on the optical disk).

This disk device includes a pivotal frame 100, and a feed chassis (mounting base) 101 mounted within this pivotal frame 100, the feed chassis comprising a plate-like member. A spindle motor (not shown) for rotating an optical disk, as well as a turn table (not shown) mounted on a rotor of the spindle motor so as to hold the optical disk, is mounted on the feed chassis 101.

A moving mechanism for moving an optical pickup 43 in a direction of the radius of the optical disk is mounted on the feed chassis 101. The optical pickup 43 has the function of applying and receiving light relative to the optical disk so as to optically read information recorded in the optical disk. In some cases, it can write information onto the optical disk.

This optical pickup 43 is mounted on a moving member 4, and the moving member 4, while guided by a pair of guide rods (not shown), can be reciprocally moved in the radial direction of the optical disk. A motor and a gear train (both of which are not shown) for moving the moving member are mounted on the feed chassis 101.

The pivotal frame 100 is mounted for pivotal movement about a pivot axis P. The pivotal frame 100 is pivotally moved when a tray, having the optical disk placed thereon, is inserted into and withdrawn from a disk device body. When the pivotal frame 100 is pivotally moved, the feed chassis 101 and the associated parts, mounted thereon, are displaced or moved between a disk drive position (a predetermined position where the reproduction of information or the like can be effected relative to the optical disk) and a standby position (a predetermined position where the feed chassis is on standby during the attachment and detachment of the optical disk). FIGS. 1 and 2 show a condition in which the feed chassis is held in the disk drive position.

A main circuit board 3 is provided below the pivotal frame 100 (FIG. 1).

The flexible wiring board-mounting structure 1 includes a strap-like flexible wiring board 2, the main circuit board (base portion) 3 having a first fixing portion 31 fixing one end portion of the flexible wiring board 2, the moving member 4 which is mounted for movement relative to the main circuit board (base portion) 3, and has a second fixing portion 41 fixing the other end portion of the flexible wiring board 2, and shape-restricting member 5 for controlling the shape of an intermediate portion 25 of the flexible wiring board 2.

The flexible wiring board 2 is a so-called FPC, and includes a plurality of wire conductors, for example, laminated with resin films. This flexible wiring board 2 is a long strap-like member, and has a suitable degree of flexibility. The wire conductors extend in a longitudinal direction of the flexible wiring board 2, and are disposed substantially parallel to one another. Terminals, corresponding respectively to one ends of the wire conductors, are formed at the one end portion 21 of the flexible wiring board 2, and terminals, corresponding respectively to the other ends of the wire conductors, are formed at the other end portion 22 of the flexible wiring board.

Dimensions of the flexible wiring board 2 are not particularly limited. In this embodiment, however, it is preferred that a width of the flexible wiring board 2 be about 15 mm to about 17 mm.

The main circuit board 3 has the first fixing portion 31 which fixes (or may be designed to releasably fix) the one end portion 21 of the flexible wiring board 2. This first fixing portion 31 has a connector, and serves to fixedly support the one end portion 21 of the flexible wiring board 2, and also serves to electrically connect the terminals, formed at the one end portion 21, respectively to corresponding terminals formed on the main circuit board 3.

The moving member (slider) 4 has a frame-like slider body 42, the optical pickup 43 mounted on the slider body 42, the second fixing portion 41 fixing the other end portion 22 of the flexible wiring board 2, and an abutment plate 44.

The frame-like slider body 42 slides along the pair of guide rods (not shown) so that the moving member 4 can reciprocally move in the radial direction (horizontal direction in FIG. 1) of the optical disk.

The other end portion 22 of the flexible wiring board 2 is fixedly supported by the second fixing portion 41, and the terminals, formed at the other end portion 22, are electrically connected respectively to corresponding terminals formed at the optical pickup 43.

The flexible wiring board 2 is disposed such that it is curved into a generally S-shape when viewed from its side as shown in FIG. 1. Namely, the flexible wiring board 2 includes a first curvature portion 23 curved in a substantially inverted manner with its front and rear sides reversed, a second curvature portion 24 curved in a direction opposite to the direction of curvature of the first curvature portion 23, and the intermediate portion 25 disposed between the first and second curvature portions 23 and 24. With this construction, the moving member 4 can be moved more smoothly.

The position of the second curvature portion 24 in the flexible wiring board 2 in the longitudinal direction is displaced in accordance with the movement of the moving member 4. Also, the radius of curvature of the second curvature portion 24 varies in accordance with the movement of the moving member 4. Namely, when the moving member 4 is located in a right position (in the drawings; hereinafter referred to as “rear position”) as shown in FIG. 1, the second curvature portion 24 is disposed relatively near to the other end portion 22, and its radius of curvature is relatively large. When the moving member 4 is located in a left position (in the drawings; hereinafter referred to as “front position”) as shown in FIG. 2, the second curvature portion 24 is disposed farther from the second end portion 22, and its radius of curvature is relatively small. That portion of the flexible wiring board, disposed in the vicinity of the first curved portion 23, is fixed to the feed chassis 101, a resin member 50 (described later) or other according to the need, and the shape of this first curvature portion is hardly changed even when the moving member 4 moves. Namely, the radius of curvature of the first curvature portion 23 is generally constant. With the above construction, the moving member 4 can be moved more smoothly.

Here, when the moving member 4 reaches its rear movement limit point or its vicinity, the radius of curvature of the second curvature portion 24 becomes the largest. Preferably, the maximum value of the curvature radius of the second curvature portion 24 is not smaller than the curvature radius of the first curvature portion 23. With this construction, the radius of curvature of the second curvature portion 24 can be made sufficiently large while reducing the distance between the feed chassis 101 and the main circuit board 3 to a relatively small value (This is advantageous for achieving a small design of the device), so that the moving member 4 can be moved smoothly while maintaining a sufficiently large radius of curvature of the second curvature portion 24.

That portion of the other end portion 22 of the flexible wiring board 22, disposed adjacent to the second curvature portion 24, is prevented by the abutment plate 44 (bent into a generally inverted flattened V-shape) from moving upward (in FIG. 1).

The shape of the intermediate portion 25 of the flexible wiring board 2 is controlled by the shape-restricting member 5 so that part of this intermediate portion 25 is deformed to project into a mountain-like shape when viewed from a side thereof. The shape-restricting member 5 includes a support portion 51 fixedly supporting a portion of the intermediate portion 25 disposed intermediate the opposite ends thereof, and at least one pressing portion of a convex shape which is disposed in the vicinity of the support portion 51, and presses other portion of the intermediate portion 25. In this embodiment, there are provided a first pressing portion 52, disposed forwardly of the support portion 51, and a second pressing portion 53 disposed rearwardly of the support portion 51.

The support portion 51, the first pressing portion 52 and the second pressing portion 53 are fixedly secured to the feed chassis 101 or are formed on the integrally formed resin member 50 (integrally molded, for example, by outer molding). These portions may be formed on the feed chassis 101.

As shown in FIG. 3, projecting piece portions (tabs) 26 and 27 are formed respectively on opposite side edges of the intermediate portion 25 intermediate the opposite ends thereof, and project in the direction of the width of the flexible wiring board 2. The support portion 51 has a pair of openings 511 and 512 for respectively receiving the two projecting piece portions 26 and 27, and the projecting piece portions 26 and 27 are inserted respectively into the openings 511 and 512, so that the projecting piece portions 26 and 27 are retained (or fixed), thereby supporting the intermediate portion 25 against movement away from the support portion.

The first pressing portion 52 includes a rib which is formed on and projects substantially perpendicularly from a lower face (FIG. 1) of the resin member 50. The lower face of the resin member 50 is substantially parallel to a lower face of the feed chassis 101. The first pressing portion 52 has a sufficient length to cover the entire width of the flexible wiring board 2 (see FIG. 3).

The second pressing portion 53 also includes a rib which is formed on and projects substantially perpendicularly from the lower face of the resin member 50 at a rear end thereof. The second pressing portion 53 has a sufficient length to cover the entire width of the flexible wiring board 2 (see FIG. 3).

A distal end (abutment portion) of each of the first and second pressing portions 52 and 53 has a generally rounded shape. With this construction, the flexible wiring board 2 is prevented from being bent abruptly, and damage of the flexible wiring board 2 and the cutting of the wires can be positively prevented. Incidentally, in the case where corners of the distal end of each of the first and second pressing portions 52 and 53 are chamfered, similar effects can be achieved.

Although the heights of the two pressing portions 52 and 53 are not particularly limited, it is preferred that the height of the first pressing portion 52 be larger than the height of the second pressing portion 53. With this construction, the intermediate portion 25 of the flexible wiring board 2 can be controlled into the more ideal shape.

The height of the first pressing portion 52 is not particularly limited. In this embodiment, however, preferably, it is about 2 mm to about 4 mm, and more preferably about 3 mm.

The height of the second pressing portion 53 is not particularly limited. In this embodiment, however, preferably, it is not larger than 1 mm, and more preferably about 0.5 mm to about 0.7 mm.

In the present invention, the provision of the second pressing portion 53 may be omitted. Further, the shape-restricting member 5 is not limited to the illustrated construction having the support portion and at least one pressing portion.

Thanks to the provision of the shape-restricting member 5, the shape of the intermediate portion 25 of the flexible wiring board 2 is so controlled that at least that portion of this intermediate portion 25, disposed at the first pressing portion 52, is deformed to project into a mountain-like shape when viewed from the side thereof Particularly, even when the moving member 4 is located at any position between its forward movement limit point and rearward movement limit point, this deformed condition is maintained.

Therefore, curling (warp in the direction of the width) will not develop in the flexible wiring board 2, and during the movement of the moving member 4, the production of an abnormal sound due to the development/elimination of the curling, as well as the production of a force (tending to instantaneously push the moving member 4) by the fluttering of the flexible wiring board 2, as encountered with the conventional construction, is prevented, and as a result the moving member 4 can be moved smoothly. Therefore, information is accurately read by the optical pickup 43, and the reliability of the disk device (the device having the flexible wiring board-mounting structure 1 mounted thereon) is enhanced.

In the above embodiment, the flexible wiring board-mounting structure 1 is applied to the disk device and particularly to the device for recording and/or reproducing information relative to the optical recording medium such as an optical disk. However, the invention is not limited to this example, but can be applied, for example, to a device of other information storage/reproduction system using a magnetic storage medium, a magneto-optic storage medium or the like. Further, the invention is not limited to such storage (recording)/reproduction device, but can be applied to other devices.

The above embodiment is directed to the disk device provided with the flexible wiring board-mounting structure 1, in which the optical disk is loaded in the horizontal direction, but the invention may be applied to the type in which the optical disk is set in the vertical direction.

Although the present invention has been shown and described with reference to specific preferred embodiments, various changes and modifications will be apparent to those skilled in the art from the teachings herein. Such changes and modifications as are obvious are deemed to come within the spirit, scope and contemplation of the invention as defined in the appended claims.

What is claimed is:

1. A structure of mounting a flexible wiring board, comprising:
a strap-like flexible wiring board, including;
a first curvature portion curved in a substantially inverted manner with its front and rear faces reversed;
a second curvature portion curved in a direction opposite to a direction of curvature of the first curvature portion; and
an intermediate portion disposed between the first and second curvature portions;
a base member, having a first fixing portion which fixes a first end portion of the flexible wiring board;
a moving member, mounted for movement relative to the base member, and the moving member having a second fixing portion which fixes the second end portion of the flexible wiring board; and
a shape-restricting member, restricting a shape of the intermediate portion so that a part of the intermediate portion is deformed to project into a convex shape when viewed from a side thereof.

2. The structure as set forth in claim 1, wherein the shape-restricting member includes a support portion fixedly supporting a portion of the intermediate portion of the flexible wiring board, and at least one pressing portion of a convex shape which is disposed in the vicinity of the support portion, and which presses other portion of the portion of the intermediate portion.

3. The structure as set forth in claim 2, wherein the pressing portion is disposed between the support portion and the first curvature portion.

4. The structure as set forth in claim 2, wherein the at least one pressing portion is a first pressing portion and a second pressing portion;
wherein the first pressing portion is disposed between the support portion and the first curvature portion; and
wherein the second pressing portion is disposed between the support portion and the second curvature portion.

5. The structure as set forth in claim 4, wherein the first pressing portion is larger in height than the second pressing portion.

6. The structure as set forth in claim 2, wherein the support portion retains or fixes opposite side edges of the intermediate portion.

7. The structure as set forth in claim 2, wherein the support portion and the pressing portion are provided on a plate-like member disposed between the base member and the moving member.

8. The structure as set forth in claim 7, wherein the pressing portion has a rib projected substantially perpendicularly from the plate-like member.

9. The structure as set forth in claim 2, wherein a distal end of the pressing portion has a rounded shape.

10. The structure as set forth in claim 1, wherein the position of the second curvature portion in the flexible wiring board is displaced in accordance with the movement of the moving member.

11. The structure as set forth in claim 1, wherein a radius of curvature of the second curvature portion varies in accordance with the movement of the moving member, while a radius of curvature of the first curvature portion is generally constant.

12. The structure as set forth in claim 1, wherein a maximum value of a radius of curvature of the second curvature portion is larger than a radius of curvature of the first curvature portion.

13. The structure as set forth in claim 1, wherein the moving member carries an optical pickup having the function to read information recorded in an optical disk.
